(19) United States
(12) Patent Application Publication
(10) Pub. No.: US 2026/0191022 A1
(43) Pub. Date: Jul. 2, 2026

(54) METHOD FOR BONDING HEAT SINK

(71) Applicant: HORNG TERNG AUTOMATION CO., LTD., Kaohsiung City (TW)

(72) Inventor: Wei-chieh WANG, Kaohsiung City (TW)

(73) Assignee: HORNG TERNG AUTOMATION CO., LTD., Kaohsiung City (TW)

(21) Appl. No.: 19/298,199

(22) Filed: Aug. 13, 2025

(30) Foreign Application Priority Data
Dec. 31, 2024 (TW) 113151657

(51) Int. Cl. H10W 70/02; H10W 72/00

(52) U.S. Cl. CPC H10W 70/027; H10W 72/07163; H10W 72/07178; H10W 72/073; H10W 72/07327; H10W 72/07341

(57) ABSTRACT

The present invention provides a method for bonding a heat sink, which includes the following steps: placing a workpiece in a lower jig; supplying an adhesive to a surface of the workpiece; after a suction head of an upper jig picks up the heat sink, moving the upper jig to assemble with the lower jig to form a closed space; evacuating the closed space to create a negative pressure environment; driving the suction head toward the workpiece and bonding the heat sink to the workpiece, during which at least one gap is formed between the heat sink and the adhesive; continuing to drive the suction head to apply pressure to the heat sink, creating a negative pressure within the gap; and restoring the negative pressure environment to atmospheric pressure, allowing the adhesive to fill the gap. The invention effectively resolves the issue of gaps forming during the bonding process.

### CORSS REFERENCE TO RELATED APPLICATIONS

This application claims priority to Taiwan Application Serial Number 113151657, filed on December 31, 2024, which is incorporated herein by reference.

### FIELD OF INVENTION

The invention relates to a method for bonding a heat sink, particularly to a method for eliminating bubbles or gaps generated during the bonding process of the heat sink.

### BACKGROUND OF INVENTION

The heat sink bonding and pressing process typically involves first applying the heat dissipation material to a die (for example, along a predetermined path), followed by pressing a heat sink onto the die to ensure even distribution of the heat dissipation material. The heat is dissipated between the die and the heat sink through the high thermal conductivity of the heat dissipation material and its close contact with both the die and the heat sink. However, during the applying or pressing process, air may be trapped in the heat dissipation material, creating gaps that negatively affect heat dissipation.

### SUMMARY OF INVENTION

One object of the present invention is to provide a heat sink bonding method to address the problems existing in the prior art.

According to the aforementioned object, a method for bonding a heat sink is provided. The method comprising steps of: placing a workpiece to be processed in a lower jig; supplying an adhesive along a predetermined path to a surface of the workpiece; after a suction head of an upper jig picks up the heat sink, moving the upper jig to assemble with the lower jig to form a closed space, wherein the heat sink and the workpiece are positioned within the closed space; evacuating the closed space to create a negative pressure environment; driving the suction head to move toward the workpiece and bonding the heat sink to the workpiece, during which at least one gap is formed between the heat sink and the adhesive; continuing to drive the suction head to move toward the workpiece to apply pressure to the heat sink, thereby creating a negative pressure within the gap; and after bonding the heat sink to the workpiece, restoring the negative pressure environment to normal atmospheric pressure, allowing the adhesive surrounding the gap to fill the gap.

According to an embodiment of the present invention, the step of evacuating the closed space and the step of driving the suction head to move toward the workpiece are performed sequentially or simultaneously.

According to an embodiment of the present invention, the rate at which the suction head is driven toward the workpiece is inversely proportional to the viscosity of the adhesive.

According to an embodiment of the present invention, when the negative pressure environment is restored to normal atmospheric pressure, the step of applying pressure to the heat sink continues to be performed.

According to an embodiment of the present invention, when the negative pressure environment is restored to normal atmospheric pressure, the suction head also stops applying pressure to the heat sink.

According to an embodiment of the present invention, after moving the upper jig to assemble with the lower jig, the method further comprises locking the upper jig and the lower jig, with a sealing ring being provided between the upper jig and the lower jig.

According to an embodiment of the present invention, the step of placing the workpiece in the lower jig comprises selecting a product fixture corresponding to the size of the workpiece and placing the product fixture in the lower jig.

According to an embodiment of the present invention, the product fixture comprises a bearing groove, and when the product fixture is positioned in the lower jig by a positioning mechanism, the center of the bearing groove is aligned with the center of the lower jig.

According to an embodiment of the present invention, the positioning mechanism comprises at least two protruding structures and at least two recessed structures corresponding to the protruding structures, wherein the protruding structures are arranged on one of the product fixture and the lower jig, and the recessed structures are arranged on the other of the product fixture and the lower jig.

According to an embodiment of the present invention, the product fixture is a cross-shaped structure, an X-shaped structure, a circular structure, or a rectangular structure, and at least three points on its sides abut against an inner wall of the lower jig.

According to the aforementioned embodiments of the present invention, the method for bonding the heat sink securely bonds the heat sink to the surface of the workpiece to be processed by controlling a negative pressure environment and applying pressure to the adhesive. This method effectively eliminates gaps between the heat sink and the workpiece, thereby ensuring high-quality bonding. It is particularly suited for precision processes, such as those in semiconductor manufacturing, and offers advantages including simplified operations, enhanced efficiency, and reduced production costs.

### DESCRIPTION OF DRAWINGS

FIG. 1 is a flowchart of a heat sink bonding method according to an embodiment of the present invention.

FIGS. 2A to 4B are schematic diagrams illustrating each step of the heat sink bonding method according to an embodiment of the present invention.

FIGS. 5A to 5C are schematic diagrams showing how the gap is filled with the adhesive according to an embodiment of the present invention.

FIG. 6 is an exploded view of a jig assembly according to an embodiment of the present invention.

FIGS. 7A to 7C are schematic diagrams showing different product fixtures according to various embodiments of the present invention.

### DETAILED DESCRIPTION OF PREFERRED EMBODIMENTS

In order to make the objects, features, and advantages of the present invention more comprehensible, preferred embodiments of the present invention will be described in detail below, together with the accompanying drawings. Furthermore, the directional terms used in the present invention, such as up, down, top, bottom, front, back, left, right, inside, outside, side, around, central, horizontal, transverse, vertical, longitudinal, axial, radial, the uppermost layer, or the lowermost layer, etc., are only for reference with respect to the orientations shown in the accompanying drawings. Therefore, these directional terms are used solely for illustrative purposes and are not intended to limit the scope of the present invention.

The present embodiment provides a method for bonding a heat sink, which is primarily used to eliminate bubbles or gaps that may form during the bonding process, thereby ensuring reliable adhesion between a heat sink, an adhesive, and a workpiece to be processed.

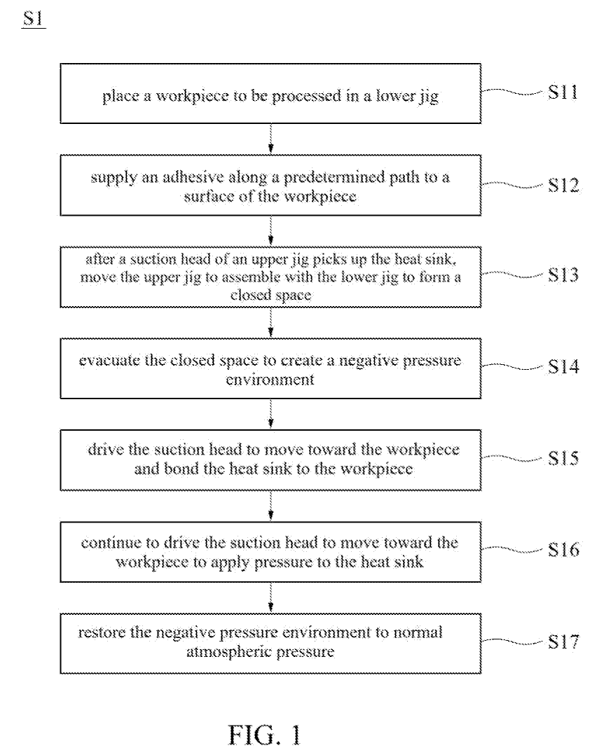

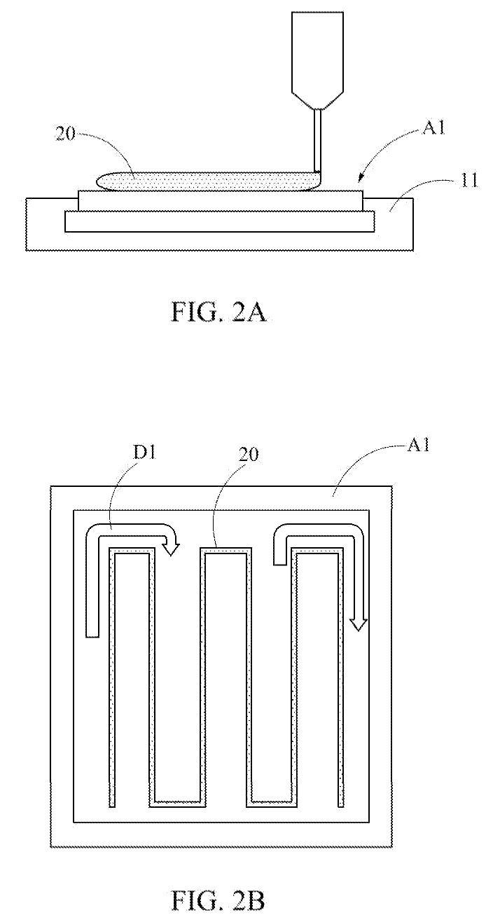

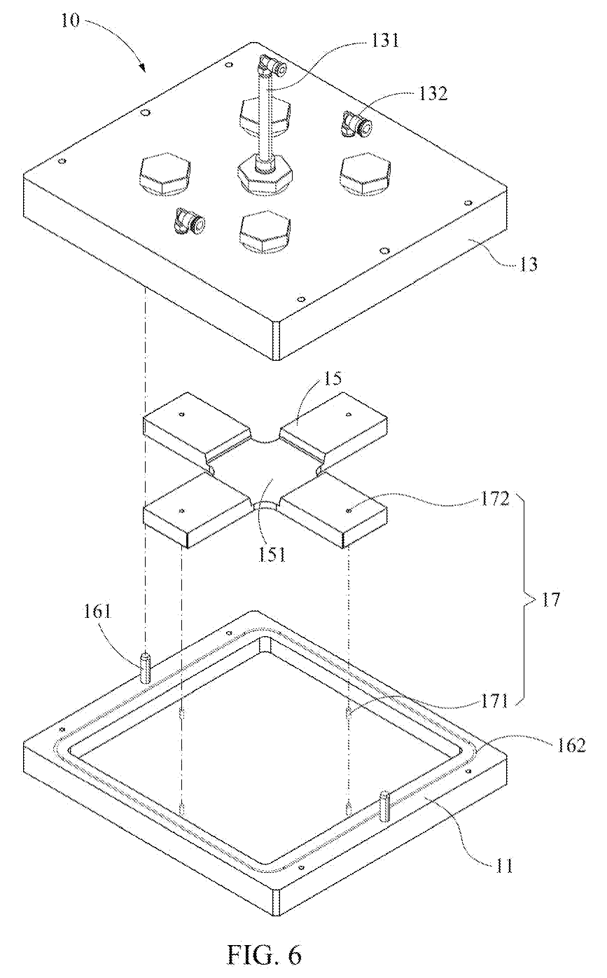

Specifically, as shown in FIGS. 1 to 4B, method S1 for bonding the heat sink of the present embodiment mainly includes the following steps. In one embodiment, the method S1 of the present embodiment can be performed using a jig assembly 10 as shown in FIG. 6 but is not limited thereto. The method S1 can also be performed using other suitable devices. In method S1, step S11 is first performed to place a workpiece to be processed (hereinafter referred to as “workpiece A1”) in a lower jig 11. Next, step S12 is performed, as shown in FIG. 2A and FIG. 2B, where an adhesive 20 is supplied to a surface of the workpiece A1 along a predetermined path D1. In a specific example, the workpiece A1 may be a semiconductor wafer, and the adhesive 20 may be a heat dissipation adhesive having appropriate viscosity to ensure that the heat sink A2 is firmly bonded to the workpiece A1, creating thermal contact after coming into contact with the workpiece A1.

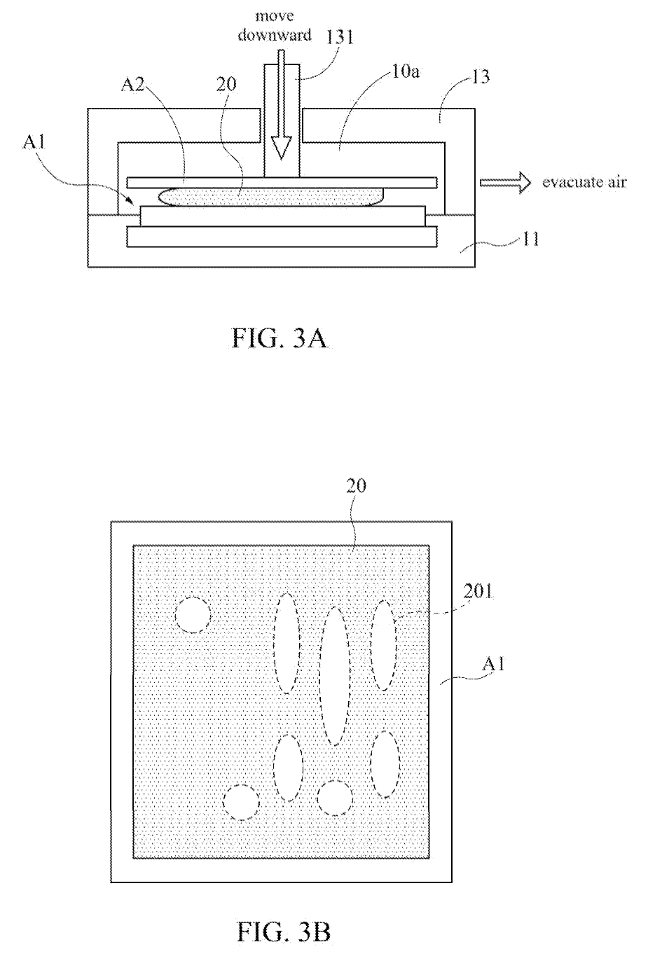

Thereafter, step S13 is performed, as shown in FIGS. 3A and 6, after the suction head 131 on the upper jig 13 picks up the heat sink A2, the upper jig 13 is moved to assemble with the lower jig 11 to form a closed space 10a. Specifically, the suction head 131, which is mounted on the upper jig 13, can be connected to a negative pressure source to generate suction and can be driven to move up and down relative to the lower jig 11. The closed space 10a is formed by the combination of the upper jig 13 and the lower jig 11, with the heat sink A2 and the workpiece A1 positioned inside. In one embodiment, the upper jig 13 can be aligned and joined with the lower jig 11 through multiple guiding pillars 161. Once the upper jig 13 and the lower jig 11 are assembled, they can be further locked to ensure a tight seal between the upper jig 13 and the lower jig 11. Additionally, a groove 162 may be provided on the surface where the lower jig 11 and the upper jig 13 connect, allowing the installation of a sealing ring. This ensures a firm connection between the upper jig 13 and the lower jig 11, thereby completely sealing the closed space 10a.

After step S13, step S14 is performed. As shown in FIG. 3A, the closed space 10a is evacuated to create a negative pressure environment. It should be noted that the negative pressure environment refers to a pressure lower than the external ambient air pressure, but greater than or equal to 0 atm. For example, when the external ambient air pressure is 1 atm, the pressure in the negative pressure environment is preferably less than 1 atm, but greater than or equal to 0 atm. Similarly, if the external ambient air pressure is 1.2 atm, the pressure in the negative pressure environment is preferably less than 1.2 atm, but greater than or equal to 0 atm. However, this is not limited to these values. Specifically, the pressure of the formed negative pressure environment can be fixed or adjusted based on the characteristics of the adhesive material. As shown in FIG. 6, the upper jig 13 is equipped with a negative pressure connector 132 to extract air from the closed space 10a. However, in other embodiments, the negative pressure connector 132 may be positioned elsewhere in the jig assembly 10. Once the negative pressure environment is established in the closed space 10a, step S15 is performed. In step S15, the suction head 131 is driven toward the workpiece A1 to bond the heat sink A2 to the workpiece A1. During the bonding process of the heat sink A2, as shown in FIGS. 3A and 3B, air may become enclosed within the adhesive 20 during the compression of the adhesive 20, leading to the formation of at least one gap 201 between the heat sink A2 and the workpiece A1. Next, step S16 is performed. In step S16, the suction head 131 is driven further toward the workpiece A1, applying pressure to the heat sink A2 and the adhesive 20, which in turn creates a negative pressure within the gap 201. In one embodiment, the rate at which the suction head 131 moves toward the workpiece A1 is inversely proportional to the viscosity of the adhesive 20, thereby ensuring even distribution of the adhesive 20 between the heat sink A2 and the workpiece A1.

It should be noted that the step of evacuating the closed space 10a (i.e., step S14) and the step of driving the suction head 131 to move toward the workpiece A1 (i.e., step S15 and step S16) are performed sequentially. Specifically, after the closed space 10a creates a negative pressure environment, the heat sink A2 is pressed toward the workpiece A1 to bond with the workpiece A1. However, this order is not intended to limit the present invention. In other embodiments, the above steps may be performed simultaneously. Specifically, after the upper jig 13 is moved to assemble with the lower jig 11 to form the closed space 10a (i.e., step S12), the closed space 10a can be evacuated (i.e., step S14) while the heat sink A2 is moved to press toward the adhesive 20 and the workpiece A1 (i.e., steps S15 and S16). Whether step S14, step S15 and step S16 are performed sequentially or simultaneously, a negative pressure can be formed in the gap 201 during the process of pressing the heat sink A2 onto the workpiece A1.

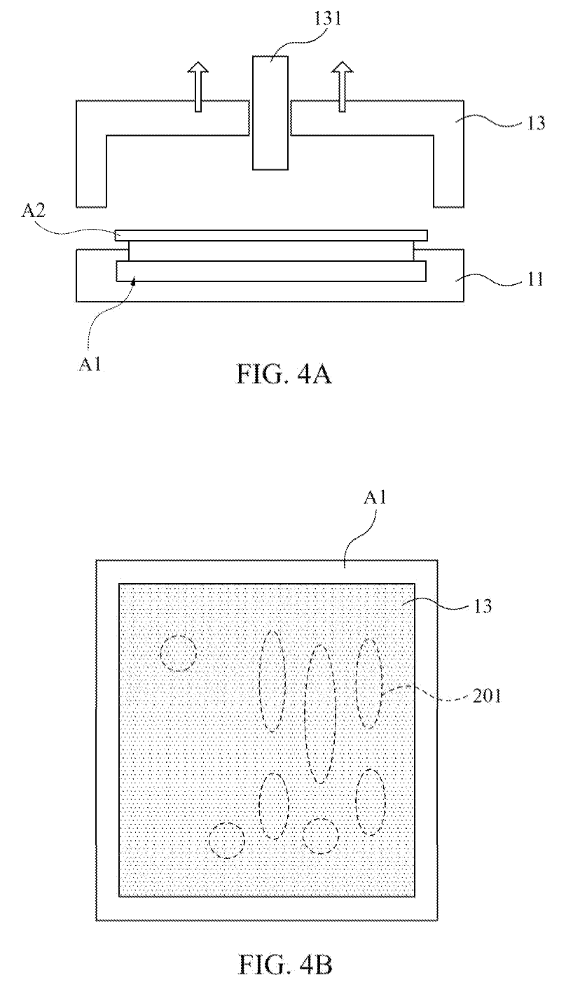

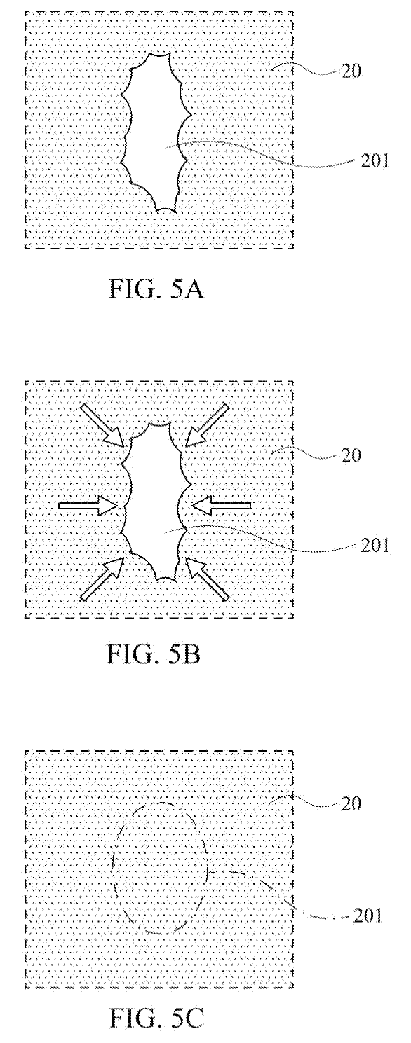

After the heat sink A2 is bonded to the workpiece A1 and a negative pressure forms in the gap 201, step S17 is performed to restore the negative pressure environment to normal pressure. As shown in FIG. 5A, when the heat sink A2 continues to press against the adhesive 20 and the workpiece A1, the compression of the adhesive 20 creates a negative pressure inside the gap 201. Once the negative pressure environment in the closed space 10a returns to normal atmospheric pressure, the principle of pressure flows from high to low causes the adhesive 20 to fill the gap 201, as shown in FIG. 5B. Finally, the gap 201 is completely filled with adhesive 20 (as shown in FIGS. 4B and 5C). In the present embodiment, as shown in FIG. 4A, the workpiece A1 with the bonded heat sink A2 can be returned to normal pressure environment by separating the upper jig 13 from the lower jig 11. Specifically, the upper jig 13 and the suction head 131 can be removed together from the lower jig 11, allowing the suction head 131 to stop applying pressure to the heat sink A2 as normal atmospheric pressure is restored. By directly separating the upper jig 13 from the lower jig 11 to restore normal atmospheric pressure, the overall operation process can be simplified, improving operational efficiency.

In other embodiments, the upper jig 13 may first be moved away from the lower jig 11 while the suction head 131 continues to exert pressure on the heat sink A2. That is, when the negative pressure environment is restored to normal atmospheric pressure, the suction head 131 maintains pressure on the heat sink A2, ensuring a more stable adhesion between the heat sink and the workpiece A1.

As shown in FIG. 1 and FIG. 6, in step S11, a product fixture 15 may be selected based on the size of the workpiece A1, and the product fixture 15 may be placed in the lower jig 11 to position the workpiece A1. Specifically, the product fixture 15 has a bearing groove 151, the size of which corresponds to the dimensions of the workpiece A1 and is used to securely hold the workpiece A1 in place. The product fixture 15 and the lower jig 11 can be fixed together using a positioning structure 17. In one embodiment, the positioning structure 17 includes at least two protruding structures 171 and at least two recessed structures 172 that correspond to the protruding structures 171.

In the embodiment of FIG. 6, the protruding structure 171 may be a convex pillar disposed on the lower jig 11, while the recessed structure 172 may be a groove or a hole located on the product fixture 15. The product fixture 15 is precisely positioned using the positioning structure 17, ensuring that the center of the bearing groove 151 aligns with the center of the lower jig 11. This further ensures that the bearing groove 151 holds the workpiece A1 in the center. As a result, the heat sink A2 can be evenly stressed during the bonding process, preventing displacement, and thereby improving the bonding quality between the heat sink A2 and the workpiece A1. In other embodiments, the dispositions of the protruding structure 171 and the recessed structure 172 are not limited to the configuration described above. Specifically, the protruding structure 171 can also be disposed on the product fixture 15, while the recessed structure 172 can be disposed on the lower jig 11, achieving the same precise positioning effect.

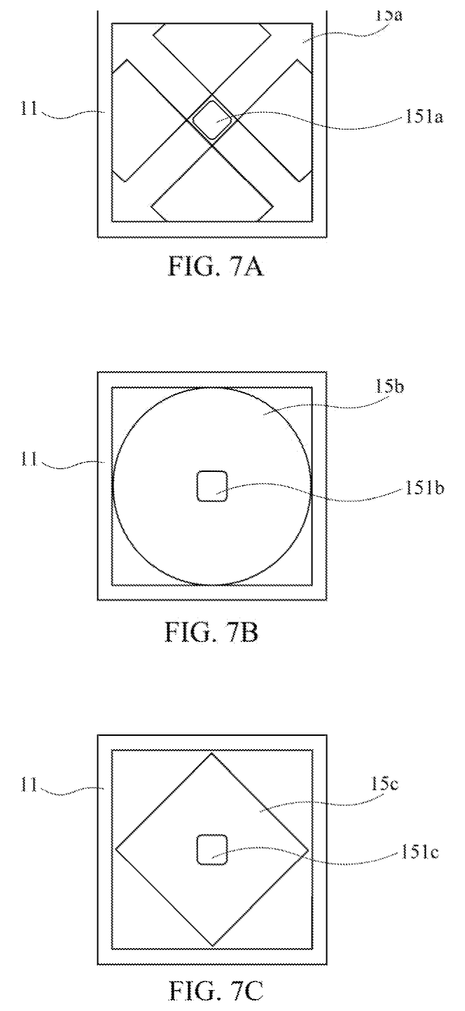

It should be noted that in the embodiment of FIG. 6, the cross-shaped structure of the product fixture 15 is shown for demonstration purposes only. In other embodiments, the product fixture 15 can be designed in different shapes according to specific requirements. For example, product fixture 15a may have an X-shaped structure as shown in FIG. 7A, product fixture 15b may have a circular structure as shown in FIG. 7B, or product fixture 15c may have a rectangular structure as shown in FIG. 7C. In one embodiment, the shape of the product fixture 15 and the shape of the lower jig 11 can be designed to be different, as long as at least three points on the sides of the product fixture 15 abut the inner wall of the lower jig 11 for proper positioning. In other words, the edges of the product fixture 15 do not need to be in full contact with the inner wall of the lower jig 11, which makes it easier for the user to replace or remove the product fixture 15. In some embodiments, a bearing groove 151a of the product fixture 15a, a bearing groove 151b of the product fixture 15b, and a bearing groove 151c of the product fixture 15c can be designed to accommodate different sizes of the workpiece A1.

As described in the above embodiments, the method for bonding the heat sink securely bonds the heat sink to the surface of the workpiece to be processed by controlling the negative pressure environment and applying pressure to the adhesive. This method efficiently resolves the issue of gaps forming between the heat sink and the workpiece, ensuring high bonding quality. It is particularly applicable to precision processes such as those used in semiconductor manufacturing, and offers advantages such as simplified operations, improved efficiency, and reduced production costs.

Although the present invention has been described in detail with reference to certain embodiments, other variations are possible. Therefore, the spirit and scope of the appended claims should not be limited to the description of the embodiments contained herein. It will be apparent to those skilled in the art that various modifications can be made to the structure of the present invention without departing from the scope or spirit of the invention. In view of the foregoing, it is intended that the present invention covers modifications and variations of this invention, provided they fall within the scope of the following claims.

1. A method for bonding a heat sink, wherein the method comprising steps of:
placing a workpiece to be processed in a lower jig;
supplying an adhesive along a predetermined path to a surface of the workpiece;
after a suction head of an upper jig picks up the heat sink, moving the upper jig to assemble with the lower jig to form a closed space, wherein the heat sink and the workpiece are positioned within the closed space;
evacuating the closed space to create a negative pressure environment;
driving the suction head to move toward the workpiece and bonding the heat sink to the workpiece, during which at least one gap is formed between the heat sink and the adhesive;
continuing to drive the suction head to move toward the workpiece to apply pressure to the heat sink, thereby creating a negative pressure within the gap; and
after bonding the heat sink to the workpiece, restoring the negative pressure environment to normal atmospheric pressure, allowing the adhesive surrounding the gap to fill the gap.

2. The method for bonding a heat sink according to claim 1, wherein the step of evacuating the closed space and the step of driving the suction head to move toward the workpiece are performed sequentially or simultaneously.

3. The method for bonding a heat sink according to claim 1, wherein the rate at which the suction head is driven toward the workpiece is inversely proportional to the viscosity of the adhesive.

4. The method for bonding a heat sink according to claim 1, wherein when the negative pressure environment is restored to normal atmospheric pressure, the step of applying pressure to the heat sink continues to be performed.

5. The method for bonding a heat sink according to claim 1, wherein when the negative pressure environment is restored to normal atmospheric pressure, the suction head also stops applying pressure to the heat sink.

6. The method for bonding a heat sink according to claim 1, wherein after moving the upper jig to assemble with the lower jig, the method further comprises locking the upper jig and the lower jig, with a sealing ring being provided between the upper jig and the lower jig.

7. The method for bonding a heat sink according to claim 1, wherein the step of placing the workpiece in the lower jig comprises selecting a product fixture corresponding to a size of the workpiece and placing the product fixture in the lower jig.

8. The method for bonding a heat sink according to claim 7, wherein the product fixture comprises a bearing groove, and when the product fixture is positioned in the lower jig by a positioning mechanism, the center of the bearing groove is aligned with the center of the lower jig.

9. The method for bonding a heat sink according to claim 8, wherein the positioning mechanism comprises at least two protruding structures and at least two recessed structures corresponding to the protruding structures, wherein the protruding structures are arranged on one of the product fixture and the lower jig, and the recessed structures are arranged on the other of the product fixture and the lower jig.

10. The method for bonding a heat sink according to claim 7, wherein the product fixture is a cross-shaped structure, an X-shaped structure, a circular structure, or a rectangular structure, and at least three points on its sides abut an inner wall of the lower jig.
